(19) United States
(12) Patent Application Publication
(10) Pub. No.: US 2018/0278145 A1
(43) Pub. Date: Sep. 27, 2018

(54) Overboost Suppressing Circuit for Boost Converter

(71) Applicant: Hitachi Automotive Systems, Ltd., Hitachinaka-shi, Ibaraki (JP)

(72) Inventor: Ryota TAKAGI, Isesaki-shi, Gunma (JP)

(21) Appl. No.: 15/760,584

(22) PCT Filed: Oct. 18, 2016
(86) PCT No.: PCT/JP2016/080809

§ 371 Date: Mar. 15, 2018

(30) Foreign Application Priority Data
Nov. 9, 2015 (JP) 2015-219126

(51) Int. Cl. H02M 1/32; H02M 3/156; G01R 31/40

(52) U.S. Cl. CPC H02M 1/32; H02M 2001/0038; G01R 31/40; H02M 3/156

(57) ABSTRACT

An overboost suppressing circuit for a boost converter that is controlled by a control circuit to boost an input voltage to a prescribed target voltage, the overboost suppressing circuit. The overboost suppressing circuit includes a detection unit that detects an overboost in which a voltage is boosted in excess of the prescribed target voltage of boost converter; and a voltage boost stop unit that, when the overboost is detected by detection unit, has the control circuit stop a voltage boost operation of boost converter, to clamp an output voltage of boost converter to a voltage higher than the prescribed target voltage and lower than or equal to a withstand voltage value of a peripheral circuit element which is a load.

### TECHNICAL FIELD

The present invention relates to an overboost suppressing circuit for a boost converter, and more specifically, relates to an overboost suppressing circuit for a boost converter, capable of suppressing an overboost in which a voltage exceeds a prescribed voltage value due to a failure, to decrease the voltage to a voltage value lower than or equal to a withstand voltage value of a peripheral circuit element.

### BACKGROUND ART

A side-slip prevention device (hereinafter, referred to as electronic stability control, “ESC”) that applies a braking force to a predetermined wheel according to a posture of a vehicle is known. In detail, when the vehicle is in an excessive oversteer state or an excessive understeer state and application of the braking force according to a vehicle motion control is required, the ESC applies the braking force to a wheel which is a control target and performs an oversteer suppression control or an understeer suppression control to stabilize a turning motion of the vehicle (for example, refer to Patent Document 1).

In order to realize a coasting idle reduction function in a vehicle, the ESC is required to have a function of continuing an output of a vehicle speed signal to the vehicle even when the battery voltage value decreases due to restart of the engine. In order to provide this function, the ESC is required to continue to supply a power supply voltage to a wheel speed sensor. Therefore, there is an increasing demand for an ESC equipped with a boost converter so that the supplied voltage is held even when such a decrease in battery voltage value occurs.

### REFERENCE DOCUMENT LIST

### Patent Document

Patent Document 1: JP 2012-66659 A

### SUMMARY OF THE INVENTION

### Problem to be Solved by the Invention

In such a boost converter, it is assumed that a failure occurs in which an output is a high voltage exceeding a prescribed voltage value. Therefore, a boost converter requires a protection function for cutting off or suppressing an output voltage when detecting an overboost, so as to ensure avoiding of a dangerous behavior of the vehicle, or smoldering or igniting of a peripheral circuit element, even in a case of failure.

As a general protection function, it is conceivable for a microcomputer to detect a high-voltage failure in which a voltage is boosted in excess of a prescribed voltage value and to stop a voltage boost operation of a boost converter. In this case, since detection of the high-voltage failure and determination of stopping of the voltage boost operation are performed by processing based on a computer program, the processing cannot be instantaneously performed. Thus, there is a concern that the voltage boost may continue also within a processing time until the high-voltage failure is detected by the microcomputer and the voltage boost operation of the boost converter is stopped, and an output voltage of the boost converter exceeds a withstand voltage value of a peripheral circuit element to which a power supply voltage is supplied to become a high voltage. Thereby, there is a concern that the peripheral circuit element may be damaged in series.

Therefore, in view of these problems, an object of the present invention is to provide an overboost suppressing circuit for a boost converter, capable of suppressing an overboost in which a voltage exceeds a prescribed voltage value due to a failure, to decrease the voltage to a voltage value lower than or equal to a withstand voltage value of a peripheral circuit element.

### Means for Solving the Problem

In order to achieve the object, according to an aspect of the present invention, an overboost suppressing circuit for a boost converter that is controlled by a control circuit to boost an input voltage to a prescribed target voltage, the overboost suppressing circuit comprising: a detection unit that detects an overboost in which a voltage is boosted in excess of the prescribed target voltage of the boost converter; and a voltage boost stop unit that, when the detection unit detects the overboost, has the control circuit stop a voltage boost operation of the boost converter, to clamp an output voltage of the boost converter to a voltage higher than the prescribed target voltage and lower than or equal to a withstand voltage value of a peripheral circuit element which is a load.

### Effects of the Invention

According to the present invention, it is possible to perform processing in real time after the overboost of the boost converter due to a failure is detected, and to suppress the overboost in which a voltage exceeds the prescribed target voltage, to decrease the voltage to a voltage lower than or equal to the withstand voltage value of the peripheral circuit element.

### BRIEF DESCRIPTION OF THE DRAWINGS

FIG. 1 is a circuit diagram illustrating a first embodiment of an overboost suppressing circuit for a boost converter according to the present invention.

FIG. 2 is a circuit diagram illustrating a generally known overboost protection circuit for a boost converter.

FIG. 3 is a timing chart illustrating an overboost protection operation of the overboost protection circuit of FIG. 2.

FIG. 4 is a flowchart for explaining an operation of the overboost suppressing circuit for the boost converter according to the present invention.

FIG. 5 is a timing chart illustrating an overboost suppressing operation according to the first embodiment.

FIG. 6 is a circuit diagram illustrating a second embodiment of the overboost suppressing circuit for the boost converter according to the present invention.

FIG. 7 is a circuit diagram illustrating a third embodiment of the overboost suppressing circuit for the boost converter according to the present invention.

FIG. 8 is a timing chart illustrating an overboost suppressing operation of the third embodiment.

### MODE FOR CARRYING OUT THE INVENTION

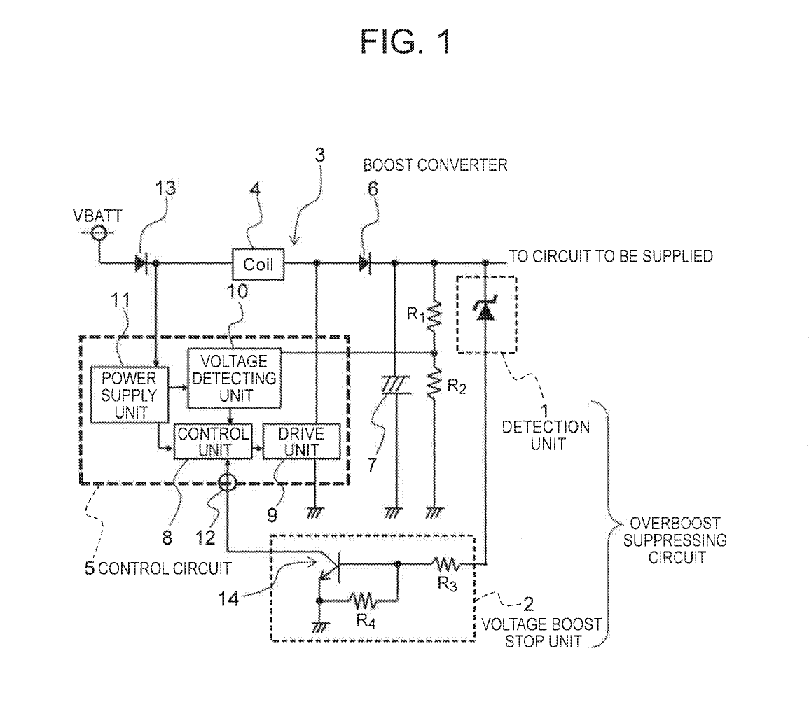

Hereinbelow, embodiments of the present invention will be described in detail with reference to the accompanying drawings. FIG. 1 is a circuit diagram illustrating a first embodiment of an overboost suppressing circuit for a boost converter according to the present invention. The overboost suppressing circuit for the boost converter that boosts the battery voltage to a prescribed target voltage value, suppresses an overboost due to a failure of the boost converter, and the overboost suppressing circuit includes a detection unit 1 and a voltage boost stop unit 2.

Here, a configuration of a boost converter 3 will first be described. Boost converter 3 boosts battery voltage V_{BATT} to prescribed target voltage V_{T}, and includes a coil 4, a control circuit 5, a diode 6, and a voltage boost capacitor 7.

Coil 4 has an input terminal connected to a battery power supply and an output terminal connected to an anode of diode 6, which will be described below, and coil 4 accumulates and discharges electric power according to a flow state and a cutoff state of a current.

Control circuit 5 controls a repeated operation of flow and cutoff of the current to coil 4, and is, for example, a semiconductor integrated circuit that includes a control unit 8, a drive unit 9, a voltage detecting unit 10, a power supply unit 11, and an operation-permission-and-prohibition-signal input terminal 12.

Here, control unit 8 generates and outputs a pulse width modulation (PWM) control signal for driving drive unit 9, which will be described below, to be turned on or off. In addition, drive unit 9 is provided between an output terminal of coil 4 and the ground (GND), and is driven to be turned on or off by the PWM control signal from control unit 8 to make a current flow to coil 4 and cut off the current, drive unit 9 being a switching element including a semiconductor element such as a MOSFET or an IGBT.

In addition, voltage detecting unit 10 monitors an output voltage (a divided voltage obtained by dividing the output voltage using two resistors R₁ and R₂) of boost converter 3, compares the monitored voltage with a reference voltage (reference voltage corresponding to the divided voltage obtained by dividing prescribed voltage value V_{T} using two resistors R₁ and R₂) corresponding to prescribed voltage value V_{T}, and outputs a differential voltage to control unit 8. Thereby, control unit 8 generates a PWM control signal of a pulse width and a duty ratio according to the differential voltage input from voltage detecting unit 10, and outputs the PWM control signal to drive unit 9.

Furthermore, power supply unit 11 receives battery voltage V_{BATT} supplied from an input terminal of coil 4, and supplies a power supply voltage to control unit 8 and voltage detecting unit 10. Operation-permission-and-prohibition-signal input terminal 12 is an input terminal of an operation permission signal for permitting an operation of control unit 8 or an operation prohibition signal for prohibiting the operation, and when the operation permission signal for setting the input terminal to a high level is input, control unit 8 performs a generation and output operation of the PWM control signal, and when the operation prohibition signal for setting the input terminal to a low level is input, control unit 8 stops the generation and output operation of the PWM control signal.

Diode 6 is for preventing electric power charged in voltage boost capacitor 7, which will be described below, from flowing back and discharging when drive unit 9 of control circuit 5 is driven to be turned on and is in a conductive state. An anode of diode 6 is electrically connected to an output terminal of coil 4, and a cathode of diode 6 is electrically connected to an output terminal of boost converter 3.

Voltage boost capacitor 7 sequentially accumulates electric power discharged from coil 4, and voltage boost capacitor 7 has one terminal connected to the cathode of diode 6 (output terminal of boost converter 3), and has the other terminal grounded. In FIG. 1, reference numeral 13 is a diode different from diode 6, a cathode of the diode is electrically connected to the input terminal of coil 4, and an anode of the diode is electrically connected to an output end of the battery power supply.

Boost converter 3 configured as described above operates as follows. That is, normally, operation-permission-and-prohibition-signal input terminal 12 of control circuit 5 is maintained at a high level (a state in which an operation permission signal is input). Thus, control unit 8 of control circuit 5 performs the generation and output operation of the PWM control signal. Thereby, drive unit 9 is driven to be turned on or off by the PWM control signal.

When, for example, a switching element of drive unit 9 driven by the PWM control signal is turned on and a current flows through coil 4, electric power is accumulated in coil 4. When the switching element is cut off and flowing of current to coil 4 is stopped, the electric power accumulated in coil 4 is discharged through diode 6 and charges voltage boost capacitor 7. Then, the charged voltage becomes an output voltage of boost converter 3.

The output voltage of boost converter 3 is divided by two resistors R₁ and R₂ (one terminal of R₂ is grounded in FIG. 1) connected in series between the output terminal of boost converter 3 and GND. A divided voltage acquired from a connection portion between two resistors R₁ and R₂ is input to voltage detecting unit 10 of control circuit 5.

Control circuit 5 compares the divided voltage input to voltage detecting unit 10 with the reference voltage, and when the divided voltage is lower than the reference voltage, that is, when the output voltage of boost converter 3 is lower than prescribed voltage value V_{T}, the control circuit generates the PWM control signal corresponding to the differential voltage output from voltage detecting unit 10 and outputs the PWM control signal to drive unit 9. Thereby, drive unit 9 performs a switching operation according to the PWM control signal to cause boost converter 3 to perform a voltage boost operation, and boosts the output voltage of boost converter 3 to prescribed voltage value V_{T}.

In addition, when the divided voltage is higher than the reference voltage, that is, when the output voltage of boost converter 3 is higher than prescribed voltage value V_{T}, control unit 8 stops outputting the PWM control signal, and stops a switching operation of drive unit 9. Thereby, the voltage boost operation of boost converter 3 stops. By doing this, the voltage boost operation and the voltage boost stop operation of boost converter 3 are repeatedly performed, and thereby, the output voltage of boost converter 3 is maintained as prescribed voltage value V_{T}.

Next, an overboost suppressing circuit for boost converter 3 according to the present invention will be described. As described above, the overboost suppressing circuit for boost converter 3 according to the present invention includes detection unit 1 and voltage boost stop unit 2.

Detection unit 1 has an input terminal electrically connected to the output terminal of boost converter 3. Detection unit 1 is provided to detect an overboost in which a voltage is boosted in excess of prescribed voltage value V_{T} of boost converter 3 due to a failure, and detection unit 1 is a Zener diode that has a cathode serving as an input terminal electrically connected to the output terminal of boost converter 3. For this Zener diode, a Zener diode having a breakdown voltage that is higher than prescribed voltage value V_{T} of boost converter 3 and is lower than or equal to a withstand voltage value of a peripheral circuit element, to which a power supply voltage is supplied (i.e., load), is selected. Herein, the overboost means that a voltage is boosted in excess of an allowable value of variation of prescribed voltage value V_{T} as in a case of a failure, and is not a boost within the allowable value of the variation of prescribed voltage value V_{T} as in a normal state.

Voltage boost stop unit 2 is arranged in a manner such that an input terminal thereof is electrically connected to the output terminal of detection unit 1 and an output terminal thereof is electrically connected to operation-permission-and-prohibition-signal input terminal 12 of control circuit 5. When the overboost due to a failure is detected in detection unit 1, voltage boost stop unit 2 has control circuit 5 stop the voltage boost operation of boost converter 3, to clamp the output voltage of boost converter 3 to a voltage higher than prescribed voltage value V_{T} and lower than or equal to the withstand voltage value of the peripheral circuit element, and voltage boost stop unit 2 includes, for example, a semiconductor switching element.

In detail, voltage boost stop unit 2 includes a semiconductor switching element 14 that has an emitter grounded, a collector electrically connected to operation-permission-and-prohibition-signal input terminal 12 of control circuit 5, and a base electrically connected to a connection portion between resistors R₃ and R₄ (one terminal of R₄ is grounded in FIG. 1) connected in series between the anode of the Zener diode serving as detection unit 1 and GND, so that a bias voltage is applied to the base. An example of semiconductor switching element 14 includes an NPN type transistor.

Next, an operation of the overboost suppressing circuit for boost converter 3 configured as described above will be described.

Reasons why the overboost in which the voltage of boost converter 3 exceeds prescribed voltage value V_{T} due to a failure occurs may be a brake of resistor R₁ of voltage dividing resistors R₁ and R₂ used for acquiring the divided voltage to monitor the boosted voltage, changing in a voltage division ratio due to deterioration of voltage dividing resistors R₁ and R₂, or a short circuit of the input terminal of voltage detecting unit 10 to GND caused by conductive foreign matter or the like.

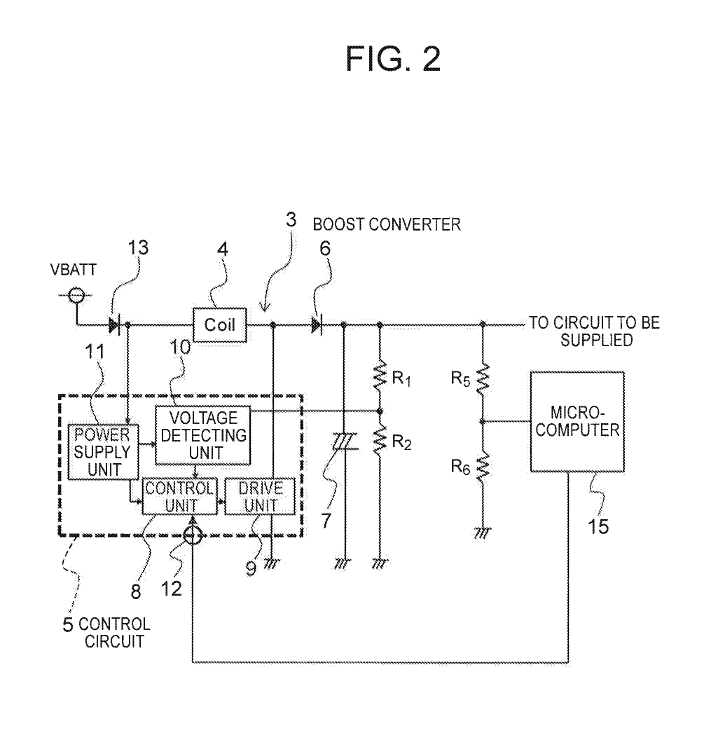

In general, a protection circuit against an overboost failure of boost converter 3 as described above may have a circuit configuration as illustrated in FIG. 2. That is, in such a configuration, a microcomputer 15, for example, detects a divided voltage obtained by dividing an output voltage using voltage dividing resistors R₅ and R₆ (one terminal of R₆ is grounded in FIG. 2) connected in series between the output terminal of boost converter 3 and GND, and then, when an output of boost converter 3 increases in excess of prescribed voltage value V_{T} due to a circuit failure and the divided voltage exceeds a threshold value (setting voltage value V_{S} previously set) for determining the overboost (hereinafter, referred to as a “failure”), control circuit 5 stops the voltage boost operation.

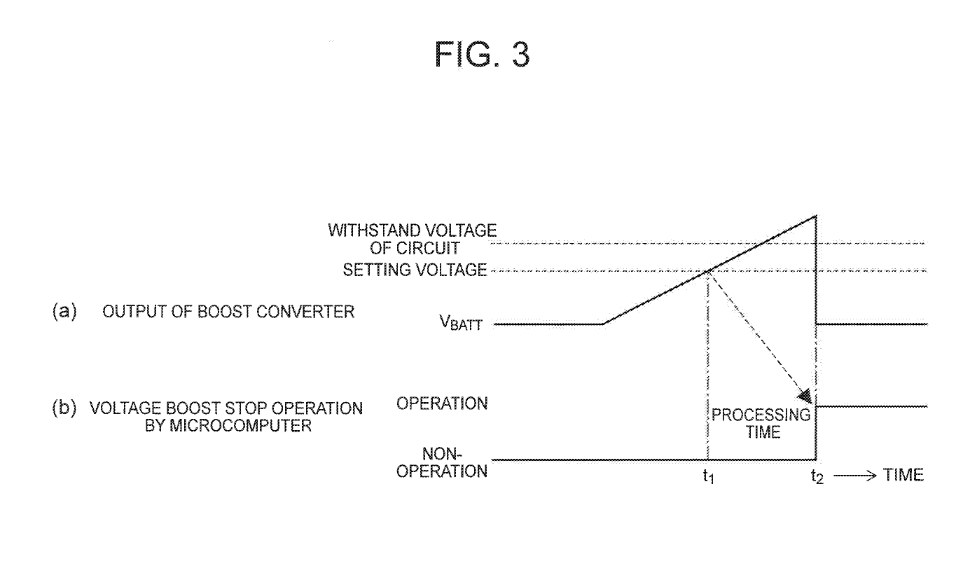

However, in such a configuration, since a series of processing for making the voltage boost operation stop, performed by control circuit 5, is executed by a computer program after determination of the failure performed by microcomputer 15, a time lag from the detection of the failure to the stop of the voltage boost operation may occur. Thus, as illustrated in (b) of FIG. 3, the voltage boost operation of boost converter 3 continues even during processing time from the detection (time t₁) of the failure to the stop (time t₂) of the voltage boost operation, and as a result, there is a concern that the boosted voltage of boost converter 3 may exceed the withstand voltage value of the peripheral circuit element, as illustrated in (a) of FIG. 3, resulting in damage to the peripheral circuit element.

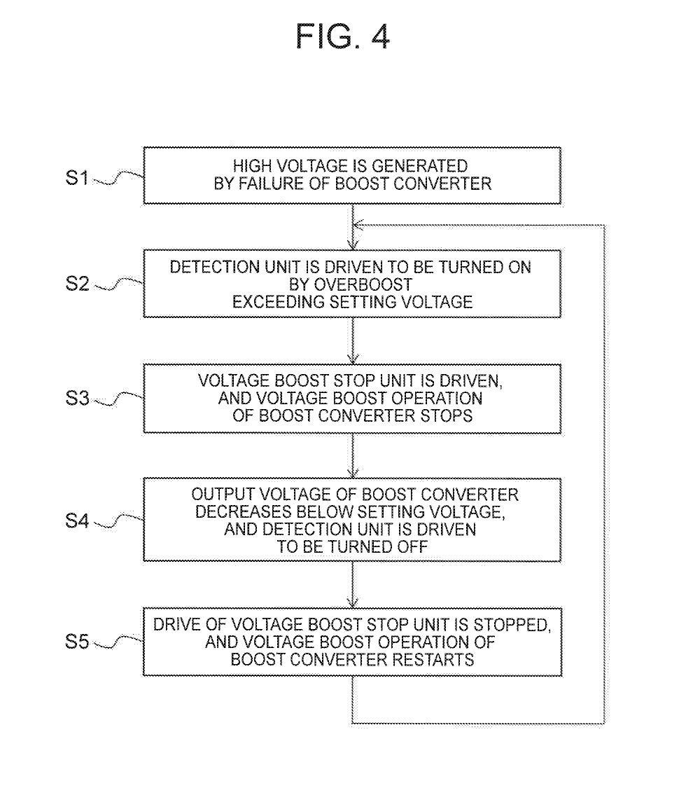

Therefore, in view of this problem, the overboost suppressing circuit for boost converter 3 according to the present invention performs detection of a failure and stopping of the voltage boost operation of boost converter 3 in real time. Hereinbelow, an operation of the overboost suppressing circuit for boost converter 3 according to the first embodiment of the present invention will be described in detail with reference to a flowchart illustrated in FIG. 4.

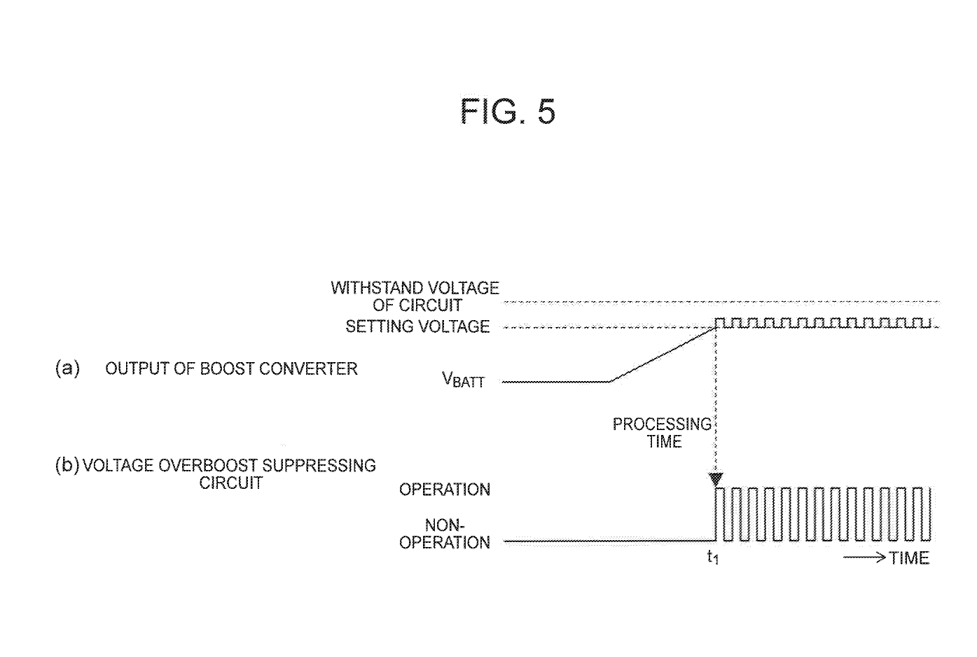

First, in step S1, a case in which boost converter 3 fails and the output voltage is boosted in excess of prescribed voltage value V_{T} is provided. In this case, when the output voltage is higher than prescribed voltage value V_{T} and exceeds setting voltage value Vs, which is set to be lower than or equal to the withstand voltage value of the peripheral circuit element (time t₁ in FIG. 5), the processing proceeds to step S2.

In step S2, detection unit 1 is driven to be turned on, and the failure of the overboost of boost converter 3 is detected. In detail, when the output voltage of boost converter 3 exceeds a breakdown voltage (setting voltage value V_{S}) of the Zener diode serving as detection unit 1 (the Zener diode is driven to be turned on), a reverse current flows from the cathode to the anode of the Zener diode. This state is referred to as failure detection performed by detection unit 1.

In step S3, voltage boost stop unit 2 is driven to stop the voltage boost operation of boost converter 3. In detail, when detection unit 1 (Zener diode) is driven to be turned on and the reverse current flows through voltage dividing resistors R₃ and R₄, a bias voltage is applied to the base of semiconductor switching element 14 serving as voltage boost stop unit 2. Thereby, semiconductor switching element 14 is driven to be turned on and a collector voltage becomes low. That is, an operation prohibition signal is input to operation-permission-and-prohibition-signal input terminal 12 of control circuit 5.

While detection unit 1 is driven to be turned on and voltage boost stop unit 2 is driven to be turned on, control unit 8 of control circuit 5 stops generating and outputting the PWM control signal. Thereby, the voltage boost operation of boost converter 3 is stopped. While the voltage boost operation of boost converter 3 is stopped, the electric power accumulated in voltage boost capacitor 7 is consumed by driving a peripheral circuit without replenishment of charge, and the output of boost converter 3 decreases. When the output of boost converter 3 decreases below setting voltage value V_{S}, that is, when the output of boost converter 3 decreases below the breakdown voltage of the Zener diode, the processing proceeds to step S4.

In step S4, detection unit 1 is driven to be turned off, and the reverse current of the Zener diode stops. Thereby, no bias voltage is applied to the base of semiconductor switching element 14 of voltage boost stop unit 2, and thereby, voltage boost stop unit 2 is driven to be turned off. By driving voltage boost stop unit 2 to be turned off, operation-permission-and-prohibition-signal input terminal 12 of control circuit 5 is in a high state, and the operation permission signal is input. The processing proceeds to step S5.

In step S5, the generation and output operation of the PWM control signal in control unit 8 of control circuit 5 starts again, and the voltage boost operation of boost converter 3 based on the PWM control signal starts again. Thereby, the output voltage of boost converter 3 starts to increase again.

When the output voltage of boost converter 3 exceeds setting voltage value V_{S} again, the processing returns to step S2, in which detection unit 1 is driven to be turned on, and then, step 3, in which the voltage boost operation of boost converter 3 is stopped, step 4, in which detection unit 1 is driven to be turned off, and step 5, in which the voltage boost operation is restarted, are sequentially performed. Thereafter, the series of operations is repeatedly performed. Thereby, the output of boost converter 3 is held (clamped) to setting voltage value V_{S} higher than prescribed voltage value V_{T} and lower than or equal to a withstand voltage value of a peripheral circuit element which is a load. Thus, even when boost converter 3 fails, the output voltage thereof is clamped to be lower than or equal to the withstand voltage value of the peripheral circuit element, and thereby, it is possible to prevent the peripheral circuit element from being damaged.

Referring to FIG. 5, it is illustrated that, when a failure is detected (time t₁) as the output voltage of boost converter 3 exceeds setting voltage value V_{S} and detection unit 1 is driven to be turned on as illustrated in (a) of FIG. 5, voltage boost stop unit 2 immediately performs the voltage boost stop operation as illustrated in (b) of FIG. 5. In addition, FIG. 5 illustrates, in (b), an operation state of the overboost suppressing circuit according to the present invention after time t₁ at which the output voltage of boost converter 3 reaches setting voltage value V_{S}. FIG. 5 illustrates, in (a), that the output voltage of boost converter 3 repeats an increase and a decrease with reference to setting voltage value V_{S} in response to an operation and a non-operation of the overboost suppressing circuit, and as a result, the output voltage of boost converter 3 is clamped to approximately setting voltage value V_{S}.

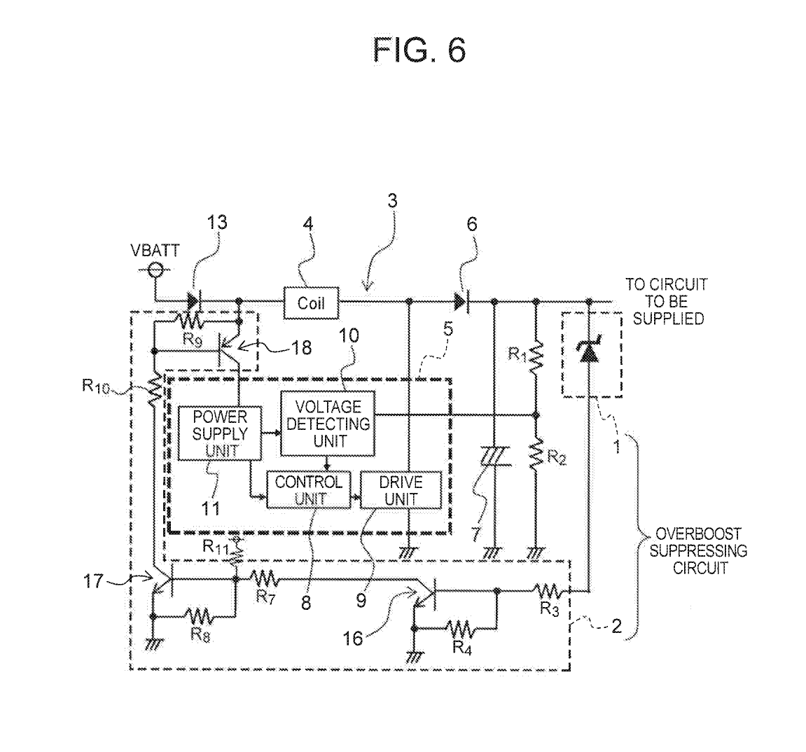

FIG. 6 is a schematic configuration diagram illustrating a second embodiment of the overboost suppressing circuit for boost converter 3 according to the present invention. The second embodiment will be described hereinafter. Here, parts different from those in the first embodiment will be described.

In the second embodiment, a part different from that in the first embodiment is a configuration of voltage boost stop unit 2. Voltage boost stop unit 2 according to the second embodiment includes a first switching element 16 that is driven to be turned on or off by driving detection unit 1 to be turned on or off, a second switching element 17 that is driven to be turned on or off by driving first switching element 16 to be turned on or off, and a third switching element 18 that is driven by driving second switching element 17 to be turned on or off.

First switching element 16 has the same configuration as semiconductor switching element 14 of voltage boost stop unit 2 according to the first embodiment, and includes, for example, an NPN type transistor having an emitter which is grounded, a base which is electrically connected to an anode of a Zener diode serving as detection unit 1 via resistor R₃ of resistors R₃ and R₄, and a collector which is electrically connected to a base of second switching element 17, which will be described below, via a resistor R₇.

Second switching element 17 has an emitter which is grounded and a base which is electrically connected to the collector of first switching element 16 via resistor R₇, a resistor R₈ is inserted between the base and GND, and a pull-up resistor R₁₁ is provided between the base and a battery power supply (the input terminal of coil 4). In addition, second switching element 17 has a collector which is electrically connected to a base of third switching element 18 via a resistor R₁₀ of resistors R₉ and R₁₀ for applying a bias voltage to the base of third switching element 18, which will be described below, and, for example, an NPN type transistor is applied as the second switching element 17. Thereby, second switching element 17 is configured such that a high base voltage is maintained by pull-up resistor R₁₁ and thereby second switching element 17 is constantly driven to be turned on, except when a failure detection operation of boost converter 3 is performed by detection unit 1.

Third switching element 18 is, for example, a PNP type transistor configured such that an emitter is connected to the battery power supply (the input terminal of coil 4), a collector is electrically connected to power supply unit 11 of control circuit 5, the base is electrically connected to a connection portion between resistors R₉ and R₁₀ (in FIG. 6, one terminal of R₁₀ is connected to the collector of second switching element 17) connected in series between the battery power supply (input terminal of coil 4) and the collector of second switching element 17, so that a bias voltage is applied to the base.

Next, an operation of the second embodiment configured as described above will be described.

When the output of boost converter 3 does not reach setting voltage value V_{S} for detecting a failure (when not in a failure detection operation), detection unit 1 is driven to be turned off and first switching element 16 of voltage boost stop unit 2 is also driven to be turned off. Thus, second switching element 17 of voltage boost stop unit 2 is supplied with a base voltage via pull-up resistor R₁, thereby being driven to be turned on, and a collector current flows to the second switching element 17 through resistors R₉ and R₁₀ of third switching element 18. Thereby, a voltage is applied to the base of third switching element 18 by the current flowing through resistors R₉ and R₁₀, and thereby, third switching element 18 is also driven to be turned on. Thus, battery voltage V_{BATT} is supplied to power supply unit 11 of control circuit 5 through third switching device 18, and thereby, each unit of control circuit 5 is driven to perform the voltage boost operation of boost converter 3 as described above.

Meanwhile, when boost converter 3 fails and the output voltage increases in excess of prescribed voltage value V_{T} (step S1 in FIG. 4) and exceeds setting voltage value V_{S} for detecting a failure, detection unit 1 is driven to be turned on (step S2 in FIG. 4), so that a reverse current flows through the Zener diode. Thereby, a bias voltage is applied to the base of first switching element 16 by a current flowing through resistors R₃ and R₄ of first switching element 16, and thereby, first switching element 16 is driven to be turned on.

When first switching element 16 is driven to be turned on, a collector potential of first switching element 16 becomes low and a base voltage of second switching element 17 decreases. Accordingly, second switching element 17 is driven to be turned off. Thereby, a collector current of second switching element 17 is cut off, and thereby, no bias voltage is applied to the base of third switching element 18 and third switching element 18 is also driven to be turned off. Thus, power supplying to power supply unit 11 of control circuit 5 is cut off, and thereby, control circuit 5 is driven to be turned off and the voltage boost operation of boost converter 3 is stopped (step S3 in FIG. 4).

When a stopped state of the voltage boost operation in boost converter 3 continues, the power accumulated in voltage boost capacitor 7 is consumed and the output voltage of boost converter 3 decreases. If the output voltage of boost converter 3 decreases below setting voltage value V_{S}, detection unit 1 is driven to be turned off (step S4 of FIG. 4). Thereby, power supplying to control circuit. 5 performed by voltage boost stop unit 2 is recovered and the voltage boost operation of boost converter 3 is restarted (step S5 in FIG. 4).

Steps S2 to S5 illustrated in FIG. 4 are repeatedly performed also in the second embodiment, in the same manner as in the first embodiment. As a result, as illustrated in (a) of FIG. 5, the output voltage of boost converter 3 is maintained (clamped) to approximately setting voltage value V_{S} higher than prescribed voltage value V_{T} and lower than or equal to a withstand voltage value of a peripheral circuit element which is a load, even during a failure.

In the second embodiment, control circuit 5 may or may not have operation-permission-and-prohibition-signal input terminal 12. In the second embodiment, in a case in which control circuit 5 has operation-permission-and-prohibition-signal input terminal 12, operation-permission-and-prohibition-signal input terminal 12 may be constantly set to be high.

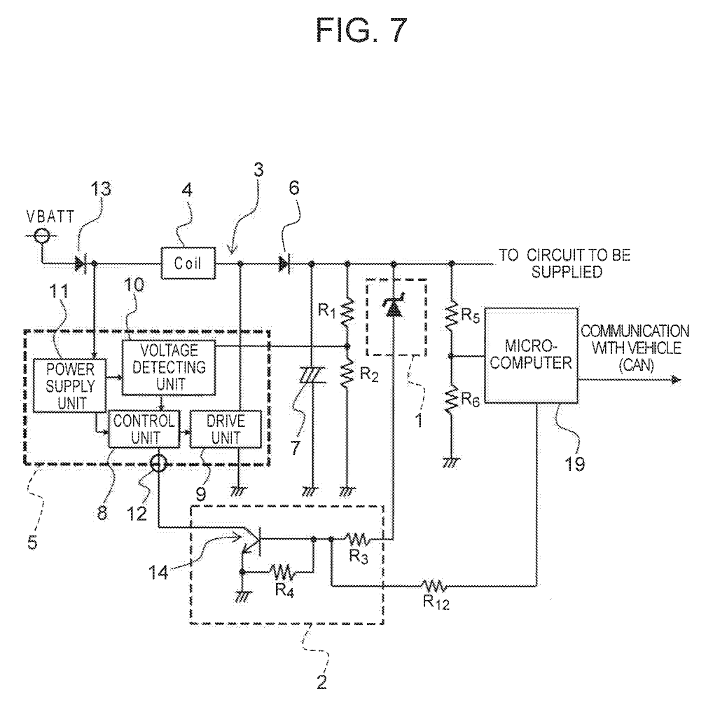

FIG. 7 is a circuit diagram illustrating a third embodiment of the overboost suppressing circuit for boost converter 3 according to the present invention. Hereinbelow, the third embodiment will be described. Here, parts different from the first embodiment will be described.

The third embodiment includes, for example, a microcomputer 19 as a failure determination circuit that determines a failure in addition to the first embodiment.

In detail, microcomputer 19 monitors a clamped state of the output voltage at the time of failure of boost converter 3 only for a preset time, and completely stops the voltage boost operation of boost converter 3, when the clamped state elapses the set time.

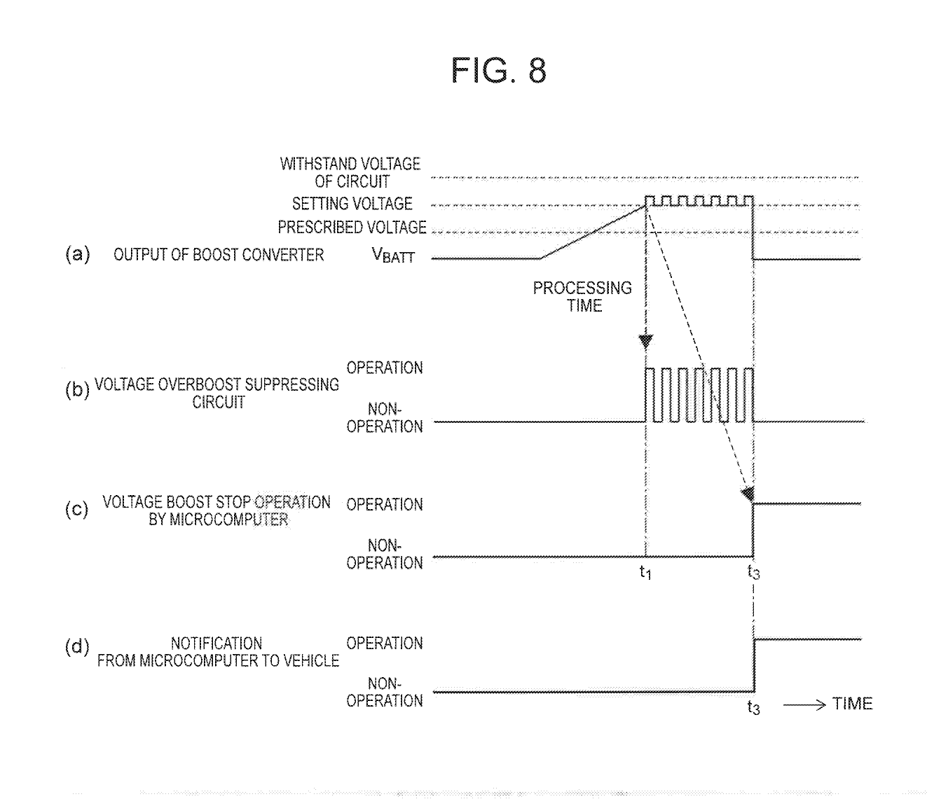

In more detail, microcomputer 19 receives a divided voltage obtained by dividing the output voltage from a connection portion between voltage dividing resistors R₅ and R₆ connected in series between the output terminal of boost converter 3 and GND, compares the divided voltage with a reference voltage (substantially equal to the divided voltage of setting voltage value V_{S}) for a failure determination, and determines the output voltage to be a failure when the divided voltage exceeds the reference voltage (time t₁ in (c) of FIG. 8).

At the same time, a clamped state of the output voltage at the time of failure of boost converter 3 is monitored for the set time, and, when the clamped state elapses the set time (time t₃ in (c) of FIG. 8), a predetermined voltage is output to the base of semiconductor switching element 14 serving as voltage boost stop unit 2 via resistor R₁₂, and a bias voltage is applied to the base. Thereby, semiconductor switching element 14 is driven to be turned on irrespective of an operation of detection unit 1, sets operation-permission-and-prohibition-signal input terminal 12 of control circuit 5 to be in a low state, and completely stops the voltage boost operation of boost converter 3.

With the complete stopping of the voltage boost operation of boost converter 3, the output voltage of boost converter 3 decreases to battery voltage V_{BATT}, as illustrated in (a) of FIG. 8. Thereby, detection unit 1 is driven to be turned off, and the overboost suppressing circuit according to the present invention appears to be in a non-operation state, as illustrated in (b) of FIG. 8.

That is, when detection unit 1 is driven to be turned off, voltage boost stop unit 2 is driven to be turned off and the voltage boost operation of boost converter 3 is restarted in the first embodiment, but voltage boost stop unit 2 is driven to be turned on by microcomputer 19 after time t₃ illustrated in (c) of FIG. 8 in the third embodiment, and thereby, a state in which operation-permission-and-prohibition-signal input terminal 12 of control circuit 5 is set to be low is maintained. Then, as illustrated in (a) of FIG. 8, the voltage boost operation of boost converter 3 is kept in a stopped state.

As such, according to the third embodiment, even when a failure occurs in boost converter 3, it is possible to hold the output voltage to be lower than or equal to a withstand voltage value of a peripheral circuit element, and it is possible to clearly determine a circuit failure by microcomputer 19, and to shift boost converter 3 and a peripheral circuit to a safe state.

In a case in which a circuit failure is clear, microcomputer 19 may completely stop the voltage boost operation of boost converter 3 and, at the same time, notify abnormality by lighting a warning lamp of a vehicle as illustrated in (d) of FIG. 8, or stop an idle reduction function.

In addition, in the third embodiment, although a case in which the failure determination circuit that determines a failure is added to the first embodiment is described, the present invention is not limited to this, and the failure determination circuit may be added to the second embodiment.

The overboost suppressing circuit for the boost converter according to the present invention is not limited to being applied to a boost converter mounted on an ESC, but can also be applied to any boost converter for boosting an input voltage to prescribed voltage value V_{T}.

### REFERENCE SYMBOL LIST

1 Detection unit
2 Voltage boost stop unit
3 Boost converter
5 Control circuit
12 Operation-permission-and-prohibition-signal input terminal
19 Microcomputer (failure determination circuit)

1. An overboost suppressing circuit for a boost converter that is controlled by a control circuit to boost an input voltage to a prescribed target voltage, the overboost suppressing circuit comprising:
a detection unit that detects an overboost in which a voltage is boosted in excess of the prescribed target voltage of the boost converter; and
a voltage boost stop unit that, when the detection unit detects the overboost, has the control circuit stop a voltage boost operation of the boost converter, to clamp an output voltage of the boost converter to a voltage higher than the prescribed target voltage and lower than or equal to a withstand voltage value of a peripheral circuit element which is a load.

2. The overboost suppressing circuit for the boost converter according to claim 1,
wherein the detection unit is a Zener diode having a breakdown voltage that is higher than the prescribed voltage value and is lower than or equal to a withstand voltage value of the peripheral circuit element.

3. The overboost suppressing circuit for the boost converter according to claim 1,
wherein the control circuit has an input terminal of a signal that permits or prohibits an operation of the control circuit, and
wherein the voltage boost stop unit outputs a signal that prohibits the operation of the control circuit to the input terminal of the control circuit, when the overboost is detected by the detection unit.

4. The overboost suppressing circuit for the boost converter according to claim 1,
wherein the voltage boost stop unit cuts off supplying of a power supply voltage to the control circuit, when the overboost is detected by the detection unit.

5. The overboost suppressing circuit for the boost converter according to claim 1, further comprising:
a failure determination circuit that determines a failure of the boost converter, if a clamped state of the overboost of the boost converter continues.
